(19) United States
(12) Patent Application Publication
(10) Pub. No.: US 2015/0305173 A1
(43) Pub. Date: Oct. 22, 2015

(54) ELECTRONIC DEVICE

(71) Applicant: Kabushiki Kaisha Toshiba, Tokyo (JP)

(72) Inventors: Tomohiro HAMADA, Tachikawa Tokyo (JP); Ryosuke SAITO, Ome Tokyo (JP); Able PAN, Taipei (TW); Aaron HSUING, Taipei (TW); Maxis LIU, Taipei (TW); Johnsan WU, Taipei (TW)

(21) Appl. No.: 14/595,420

(22) Filed: Jan. 13, 2015

(30) Foreign Application Priority Data
Apr. 17, 2014 (JP) 2014-085865

(51) Int. Cl. H05K 5/02; H05K 5/00

(52) U.S. Cl. CPC H05K 5/02; H05K 5/0017; H05K 5/0247

(57) ABSTRACT

In general, according to one embodiment, an electronic device includes a first component, a wall member, and an accommodating part. The wall member includes a plurality of first walls surrounding the first component, a gap being formed between at least one of the first walls and the first component. The accommodating part is between the first component and the at least one of the first walls, and is configured to accommodate a second component.

### CROSS-REFERENCE TO RELATED APPLICATIONS

This application is based upon and claims the benefit of priority from Japanese Patent Application No. 2014-085865, filed Apr. 17, 2014, the entire contents of which are incorporated herein by reference.

### FIELD

Embodiments described herein relate generally to an electronic device.

### BACKGROUND

Electronic devices comprise various components.

In general, electronic devices are desired to be thinned.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention.

FIG. 1 is an exemplary perspective view illustrating a portable computer according to a first embodiment;

FIG. 2 is an exemplary plan view illustrating a display part in the first embodiment;

FIG. 3 is an exemplary perspective view illustrating a part of the display part in the first embodiment;

FIG. 4 is an exemplary cross-sectional view illustrating the display part along the line F4-F4 in FIG. 2, in the first embodiment;

FIG. 5 is an exemplary cut-out plan view illustrating a part of the display part in the first embodiment;

FIG. 6 is an exemplary cross-sectional view illustrating the display part along the line F6-F6 in FIG. 2, in the first embodiment; and

FIG. 7 is an exemplary cross-sectional view illustrating the display part according to a second embodiment.

### DETAILED DESCRIPTION

In general, according to one embodiment, an electronic device includes a first component, a wall member, and an accommodating part. The wall member includes a plurality of first walls surrounding the first component, a gap being formed between at least one of the first walls and the first component. The accommodating part is between the first component and the at least one of the first walls, and is configured to accommodate a second component.

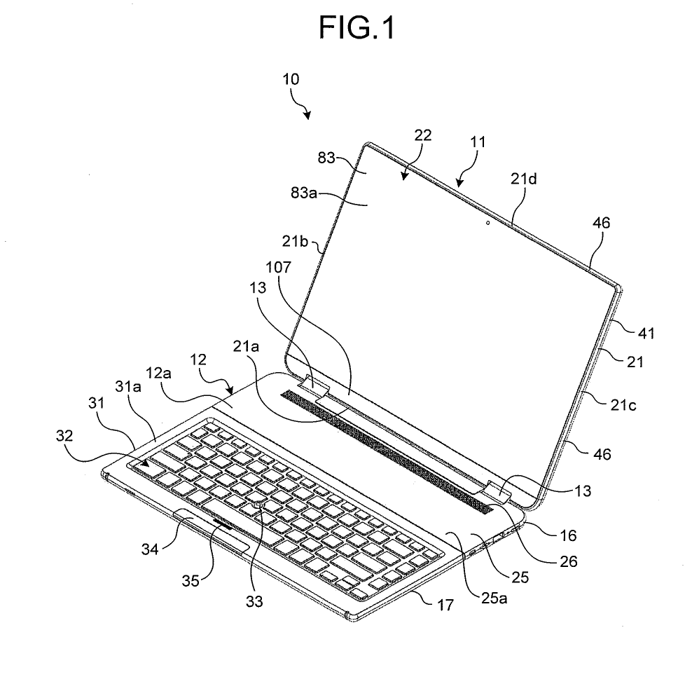

The following describes a first embodiment with reference to FIG. 1 to FIG. 6. Basically, in this description, a user side is defined as the front, a side away from the user is defined as the rear, a left side when viewed from the user is defined as the left, a right side when viewed from the user is defined as the right, an upper side when viewed from the user is defined as an upward direction, and a lower side when viewed from the user is defined as a downward direction. Each of components according to embodiments and description of the component may be expressed in a plurality of ways. The component and the description thereof are not prevented from being expressed in another way that is not described herein. The component and the description thereof that are not expressed in a plurality of ways are not prevented from being expressed in another way.

FIG. 1 is a perspective view illustrating a portable computer 10 according to the first embodiment. The portable computer 10 is an example of an electronic device. Examples of the electronic device include, but are not limited to, a television receiving device, a display, a cellular phone, a smartphone, a tablet computer, a personal digital assistant (PDA), a portable music player, a digital camera, a video camera, a game machine, and other electronic devices.

As illustrated in FIG. 1, the portable computer 10 comprises a display part 11, a base 12, and two hinges 13. The display part 11 may also be referred to as, for example, a displaying part, a module, a unit, or a portion. The base 12 may also be referred to as, for example, a main body, a module, a unit, or a portion. The hinge part 13 may also be referred to as, for example, a connection part, a connecting part, a coupling part, a rotating part, an intermediate part, or an interposing part.

An end portion of the display part 11 is rotatably connected to an end portion of the base 12 via the hinges 13. The base 12 comprises a base unit 16 connected to the display part 11 via the hinges 13 and a keyboard module 17 removably mounted to the base unit 16. The base unit 16 may also be referred to as, for example, a coupling part, a docking part, a rotating part, a supporting part, a portion, or a component. The keyboard module 17 may also be referred to as, for example, a coupling part, a docking part, a detachable part, a portion, or a component.

The display part 11 can be moved to a closed position, a clamshell position, a tent position, and a tablet position by being rotated with respect to the base 12 via the hinges 13. In the closed position, the display part 11 covers an upper face 12a of the base 12. In the clamshell position, the display part 11 is erected from the end portion of the base 12 toward a side to which the upper face 12a of the base 12 faces. In the tent position, the display part 11 is erected from the end portion of the base 12 toward a side opposite to the upper face 12a of the base 12. In the tablet position, the display part 11 covers a face opposite to the upper face 12a of the base 12. FIG. 1 illustrates the display part 11 in the clamshell position.

The display part 11 comprises a first housing 21 and a display unit 22. The first housing 21 is an example of a housing, and may also be referred to as an exterior part, an accommodating part, a storage part, a member, or a wall, for example. The display unit 22 may also be referred to as, for example, a display device, a displaying part, an assembly, a component, or a member.

The first housing 21 is formed to be a flat and substantially rectangular parallelepiped box. The first housing 21 may be formed to be another shape. The two hinges 13 are rotatably mounted to a lower end 21a of the first housing 21. The lower end 21a of the first housing 21 faces downward when the display part 11 is in the clamshell position.

The base unit 16 comprises a second housing 25. The second housing 25 is formed to be a flat and substantially rectangular parallelepiped box and accommodates various components such as a substrate and a cooling device. The substrate may be, for example, a printed circuit board (PCB) such as a motherboard on which a central processing unit (CPU) is mounted and a daughter board that is connected to the motherboard. The substrate may also comprise a flexible printed circuit board (FPC).

An upper face 25a of the second housing 25 forms a part of the upper face 12a of the base 12. A plurality of vent holes 26 are provided on the upper face 25a of the second housing 25. The cooling device accommodated in the second housing 25 comprises, for example, a fan, and sucks or exhausts air through the vent holes 26.

The keyboard module 17 comprises a third housing 31, a keyboard 32, a pointing stick 33, a click button 34, and an eject lever 35. The keyboard module 17 also comprises a device that wirelessly communicates with the base 12 and a battery, and can be used separately from the base unit 16.

The third housing 31 is formed to be a flat and substantially rectangular parallelepiped box. An upper face 31a of the third housing 31 forms a part of the upper face 12a of the base 12. The keyboard 32, the pointing stick 33, the click button 34, and the eject lever 35 are arranged on the upper face 31a of the third housing 31.

The keyboard 32, the pointing stick 33, and the click button 34 are operated by the user for inputting information to the portable computer 10. When the eject lever 35 is operated, the base unit 16 and the keyboard module 17 are decoupled from each other.

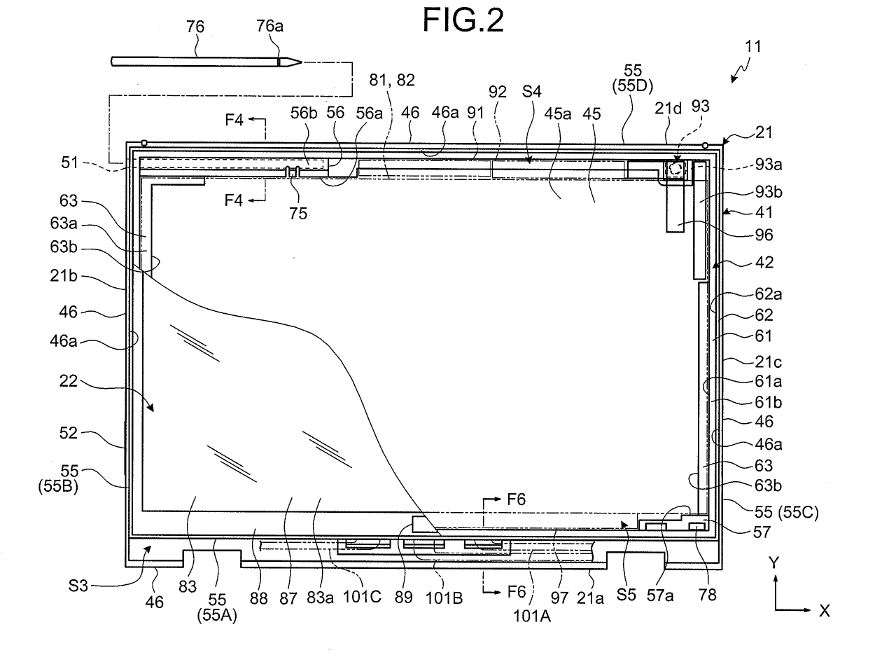

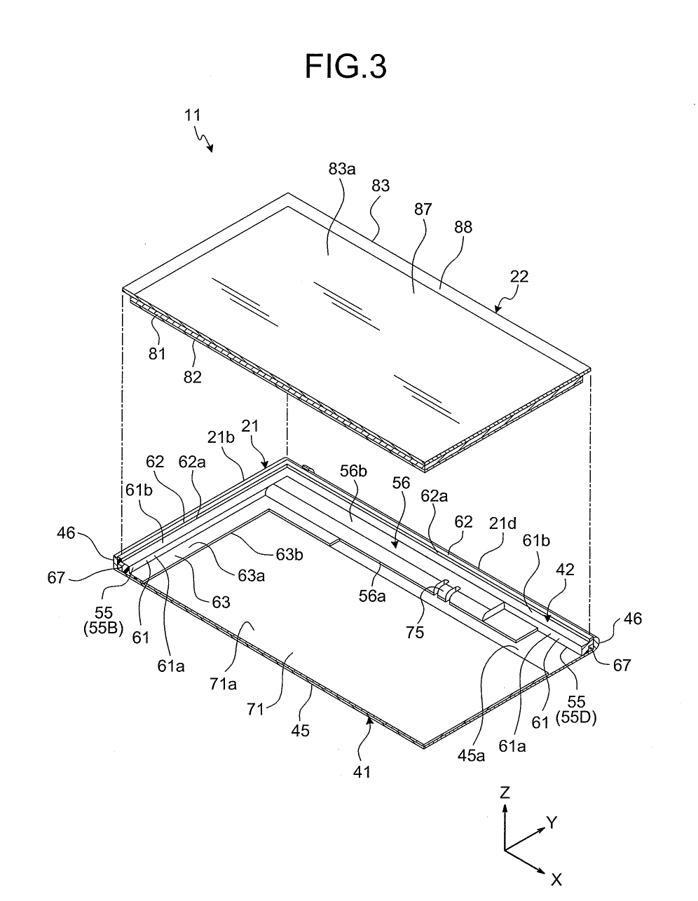

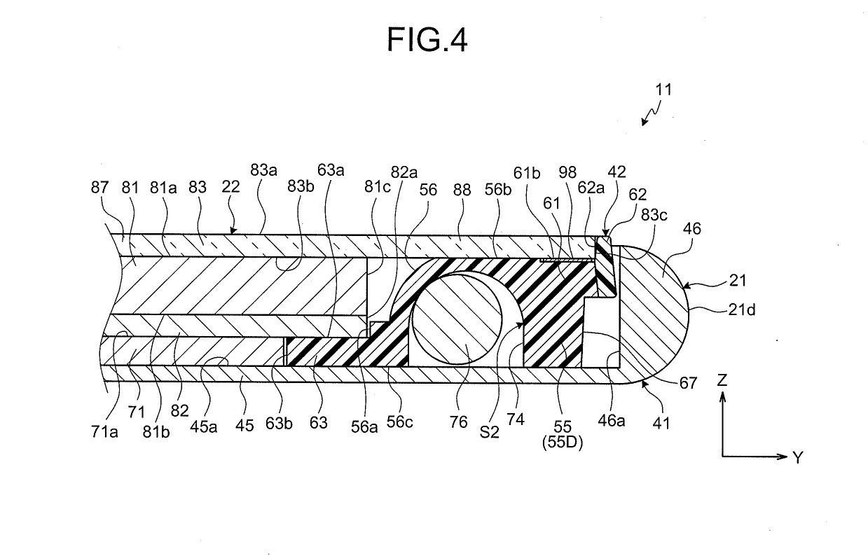

FIG. 2 is a partially cut-out plan view illustrating the display part 11. FIG. 3 is a perspective view illustrating a part of the display part 11 in which the first housing 21 and the display unit 22 are separated from each other. FIG. 4 is a cross-sectional view illustrating the display part 11 along the line F4-F4 in FIG. 2.

As illustrated in the drawings, an X-axis, a Y-axis, and a Z-axis are defined herein. The X-axis, the Y-axis, and the Z-axis are orthogonal to each other. The X-axis is along the width of the display part 11. The Y-axis is along the length of the display part 11. The Z-axis is along the thickness of the display part 11.

As illustrated in FIG. 2, the first housing 21 comprises a back cover 41 and a frame 42. The back cover 41 is an example of a second member, and may also be referred to as a covering part, a lid, a wall, a component, a member, or a portion, for example. The frame 42 is an example of a wall member and a frame member, and may also be referred to as a holding part, a surrounding part, a braking part, a wall, a component, a member, or a portion, for example.

The back cover 41 is made of, for example, aluminum alloy. The back cover 41 can be made of other material. The back cover 41 comprises a back wall 45 and a plurality of peripheral walls 46. The peripheral walls 46 are examples of a plurality of third walls.

The back wall 45 is formed to have a substantially rectangular shape (quadrangle). The back wall 45 comprises a substantially flat bottom face 45a. The bottom face 45a may comprise a boss to which other components are mounted, a groove through which a cable passes, and various portions arranged thereon.

Each of the peripheral walls 46 is erected from the bottom face 45a of the back wall 45 at the end portion of the back wall 45. The peripheral walls 46 are arranged to be a frame having a substantially rectangular shape (quadrangle). The arrangement of the peripheral walls 46 is not limited thereto.

The peripheral walls 46 form the lower end 21a, a left side 21b, a right side 21c, and an upper end 21d of the first housing 21, respectively. The left side 21b faces to the left when the display part 11 is in the clamshell position. The right side 21c faces to the right when the display part 11 is in the clamshell position. The upper end 21d faces upward when the display part 11 is in the clamshell position.

Each of the peripheral walls 46 that form the left side 21b, the right side 21c, and the upper end 21d of the first housing 21 comprises a flat inner face 46a. Each inner face 46a faces to the inside of the first housing 21. The inner face 46a of the peripheral wall 46 and the bottom face 45a of the back wall 45 are substantially orthogonal to (intersect with) each other. A face facing to the inside of the first housing 21 of the peripheral wall 46 that forms the lower end 21a of the first housing 21 is recessed.

An insertion opening 51 and a volume adjusting button (hereinafter, referred to as a button) 52 are arranged on the peripheral wall 46 that forms the left side 21b of the first housing 21. The insertion opening 51 is an example of a first opening, and may also be referred to as an insertion part, an inserting part, an opening part, or a hole, for example. The button 52 is an example of a fourth component, and may also be referred to as a member, for example.

The insertion opening 51 is arranged in the vicinity of the upper end 21d of the first housing 21. The insertion opening 51 is a substantially circular hole that opens toward the outside of the first housing 21. The insertion opening 51 is connected to a cut-out that is provided from the peripheral wall 46 forming the left side 21b of the first housing 21 to the back face 45a.

The button 52 is a button for increasing or decreasing sound volume of a sound output from the portable computer 10, for example. The button 52 extends along a longitudinal direction of the peripheral wall 46. For example, the sound volume of the portable computer 10 is increased when one end of the button 52 is pressed, and the sound volume of the portable computer 10 is decreased when the other end of the button 52 is pressed.

The frame 42 is formed to be a rectangular (quadrangle) frame. The frame 42 may have another shape. The frame 42 is fixed to, for example, the bottom face 45a of the back wall 45 with an adhesive agent. The frame 42 may be attached to the back cover 41 using other means such as a claw and a screw. The frame 42 may also be fixed to other places such as the peripheral wall 46.

The frame 42 comprises four walls 55, a first accommodating part 56, and a second accommodating part 57. The wall part 55 is an example of a first wall, and may also be referred to as an extending part, a supporting part, a holding part, a surrounding part, a contact part, a braking part, a member, or a portion, for example. The first accommodating part 56 is an example of an accommodating part, and may also be referred to as a holding part, an insertion part, a housing part, a component, or a portion.

In the following description, the four walls 55 may be individually referred to as walls 55A, 55B, 55C, and 55D. Description common to the walls 55A, 55B, 55C, and 55D is about the walls 55.

The walls 55A and 55D extend along the X-axis. The wall part 55A is arranged apart from the peripheral wall 46 that forms the lower end 21a of the first housing 21. The wall 55D is in contact with the inner face 46a of the peripheral wall 46 that forms the upper end 21d of the first housing 21. A gap may be formed between the wall 55D and the inner face 46a of the peripheral wall 46.

The walls 55B and 55C extend along the Y-axis. The wall part 55B is in contact with the inner face 46a of the peripheral wall 46 that forms the left side 21b of the first housing 21. The wall part 55C is in contact with the inner face 46a of the peripheral wall 46 that forms the right side 21c of the first housing 21. A gap may be formed between the wall part 55B and the inner face 46a of the peripheral wall 46, and between the wall part 55C and the inner face 46a of the peripheral wall 46.

As illustrated in FIG. 3, the wall part 55 comprises a first edge portion 61, a second edge portion 62, and a supporting part 63. The first edge portion 61 and the supporting part 63 are examples of a first formed portion. The second edge portion 62 is an example of a second formed portion.

The first edge portion 61 is made of, for example, synthetic resin such as polycarbonate. The polycarbonate is an example of first material. The first edge portion 61 may be made of other material. The first edge portion 61 is formed to have a substantially quadrangle bar shape, and extends along the corresponding peripheral wall 46. The shape of the first edge portion 61 is not limited thereto.

The first edge portion 61 comprises a first inner peripheral face 61a and a first supporting face 61b. The first inner peripheral face 61a is formed to be substantially flat, and is substantially orthogonal to (intersects with) the bottom face 45a of the back wall 45. The first supporting face 61b is formed to be substantially flat, is substantially in parallel with the bottom face 45a of the back wall 45, and is substantially orthogonal to (intersects with) the first inner peripheral face 61a.

The second edge portion 62 is made of, for example, thermoplastic polyurethane (TPU). The TPU is an example of second material. The material of the second edge portion 62 has higher elasticity than that of the material of the first edge portion 61. The second edge portion 62 may be made of other material.

The second edge portion 62 is integrally formed with the first edge portion 61. For example, the first edge portion 61 and the second edge portion 62 are formed through two-color molding (double molding). The first edge portion 61 and the second edge portion 62 may be formed through other methods.

The second edge portion 62 is formed to have a plate shape protruding from the first supporting face 61b of the first edge portion 61, and extends along the corresponding peripheral wall 46. The second edge portion 62 is at least partially in contact with the inner face 46a of the corresponding peripheral wall 46.

The second edge portion 62 comprises a second inner peripheral face 62a. The second inner peripheral face 62a is formed to be substantially flat, and is substantially orthogonal to (intersects with) the first supporting face 61b of the first edge portion 61. The second inner peripheral face 62a is closer to the corresponding peripheral wall 46 than the first inner peripheral face 61a of the first edge portion 61. In other words, the second inner peripheral face 62a of the second edge portion 62 is positioned on the outer side than the first inner peripheral face 61a of the first edge portion 61.

The supporting part 63 is made of the same material as that of the first edge portion 61, and integrally formed with the first edge portion 61. The supporting part 63 extends from the first inner peripheral face 61a of the first edge portion 61 along the bottom face 45a of the back wall 45. The supporting part 63 comprises a second supporting face 63a and a third inner peripheral face 63b.

The second supporting face 63a is formed to be substantially flat, is substantially in parallel with the bottom face 45a of the back wall 45, and is substantially orthogonal to (intersects with) the first inner peripheral face 61a. Ina direction along the Z-axis, a distance between the bottom face 45a of the back wall 45 and the second supporting face 63a of the supporting part 63 is smaller than a distance between the bottom face 45a of the back wall 45 and the first supporting face 61b of the first edge portion 61. The third inner peripheral face 63b is substantially orthogonal to (intersects with) the bottom face 45a of the back wall 45.

A groove 67 is provided to each of the walls 55B, 55C, and 55D. The groove 67 is an example of a second recessed part, and may also be referred to as an indentation, an accommodating part, or a storage part, for example. The groove 67 is a cut-out opened toward the back wall 45 and the corresponding peripheral wall 46, and extends along the corresponding peripheral wall 46.

As illustrated in FIG. 4, the groove 67 is covered with the back wall 45 and the peripheral wall 46 when the frame 42 is mounted to the back cover 41. The groove 67 covered with the back wall 45 and the peripheral wall 46 forms a first accommodation space S1 extending along the corresponding peripheral wall 46.

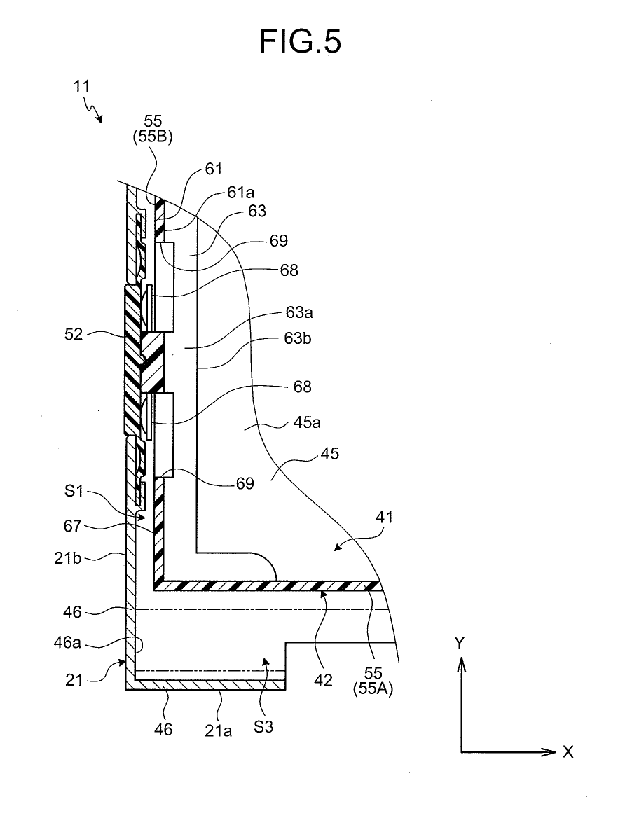

FIG. 5 is a cut-out plan view illustrating part of the display part 11. As illustrated in FIG. 5, part of the button 52 and two switches 68 are arranged in the first accommodation space S1 formed with the groove 67 of the wall part 55B, the back wall 45, and the corresponding peripheral wall 46. In other words, the groove 67 accommodates the button 52 and the switches 68. Each of the switches 68 is an example of a fourth component.

Each of the switches 68 is electrically connected to the substrate of the base unit 16 via a cable, for example. Each of the switches 68 faces each end portion of the button 52. When the button 52 is operated from the outside of the first housing 21, either one of the switches 68 is pressed against the end portion of the button 52.

Two first inserting holes 69 are provided to the wall part 55B. The first inserting holes 69 are positioned corresponding to the switches 68. The cable extending from the switch 68 passes through the corresponding first inserting hole 69. The cable extending from the switch 68 may pass through the first accommodation space S1.

As illustrated in FIG. 3, the display part 11 further comprises a battery 71. The battery 71 is an example of a fifth component, and may also be referred to as a supporting part, a flat part, or a member, for example. The battery 71 is accommodated in the first housing 21. The battery 71 supplies electric power to the portable computer 10.

The battery 71 is formed to be a plate having a substantially rectangular shape (quadrangle). The battery 71 is arranged on the bottom face 45a of the back wall 45, and is surrounded by the walls 55. The battery 71 is in contact with and held by the third inner peripheral face 63b of the supporting part 63 of the wall 55. In other words, the battery 71 is surrounded by the supporting part 63. The battery 71 may be fixed to the bottom face 45a of the back wall 45 with double-sided tape, for example. A gap may be formed between the battery 71 and the third inner peripheral face 63b of the supporting part 63.

The battery 71 comprises a third supporting face 71a. The third supporting face 71a is an example of a flat face. The third supporting face 71a is substantially in parallel with the bottom face 45a of the back wall 45. The third supporting face 71a and the second supporting face 63a of the supporting part 63 form substantially the same plane. The third supporting face 71a may protrude more than the second supporting face 63a of the supporting part 63, and may be recessed more than the second supporting face 63a of the supporting part 63.

The first accommodating part 56 is integrally formed with the walls 55B and 55D. The first accommodating part 56 is formed to have a substantially rectangular shape (quadrangle), and extends from the first edge portion 61 of the wall part 55B along the wall 55D. In other words, the first accommodating part 56 is a portion projecting from the walls 55B and 55D, and is a portion formed by extending the width of the wall 55D. The first accommodating part 56 may be a component separated from the wall 55. As illustrated in FIG. 4, the first accommodating part 56 comprises a first face 56a, a second face 56b, and a third face 56c. The first face 56a is an example of a second wall.

The first face 56a of the first accommodating part 56 comprises a portion that is substantially in parallel with the first inner peripheral face 61a of the first edge portion 61 of the wall 55D. The second face 56b of the first accommodating part 56 is substantially in parallel with the first supporting face 61b of the second edge portion 62, and is formed to be substantially flat. The third face 56c of the first accommodating part 56 is positioned on a side opposite to the second face 56b, and faces the bottom face 45a of the back wall 45.

A recessed part 74 is provided to the first accommodating part 56. The recessed part 74 is an example of a first recessed part, and may also be referred to as a groove, an indentation, an accommodating part, a storage part, or a portion, for example. The recessed part 74 opens toward the third face 56c of the first accommodating part 56 and extends along the wall 55D.

In a direction along the X-axis, one end portion of the recessed part 74 is connected to the insertion opening 51 of the peripheral wall 46. In other words, the recessed part 74 is opened via the insertion opening 51. The other end portion of the recessed part 74 is closed. When the frame 42 is mounted to the back cover 41, the recessed part 74 is covered with the back wall 45. The recessed part 74 covered with the back wall 45 forms a second accommodation space S2 extending along the wall 55D.

As illustrated in FIG. 2, the first accommodating part 56 further comprises a locking part 75. The locking part 75 is a portion that can be elastically deformed. The locking part 75 comprises a projection projecting into the recessed part 74. When the locking part 75 is elastically deformed, the projection is moved, for example, between a position where it projects into the recessed part 74 and a position where it is recessed.

The portable computer 10 further comprises a touch pen 76. The touch pen 76 is an example of a second component and a pen, and may also be referred to as a stylus pen, a digitizer pen, a pointing device, or a member. The touch pen 76 is removably accommodated in the second accommodation space S2. In other words, the recessed part 74 can accommodate the touch pen 76.

The touch pen 76 is inserted from the insertion opening 51 of the peripheral wall 46 into the recessed part 74 (second accommodation space S2). The touch pen 76 has a substantially cylindrical shape, and is accommodated in the recessed part 74 extending along the wall 55D. An end portion of the touch pen 76 accommodated in the recessed part 74 projects in a radial direction of the touch pen 76, and is caught by the cut-out connected to the insertion opening 51.

A locked groove 76a is provided to the touch pen 76. The locked groove 76a extends, for example, in a circumferential direction of the touch pen 76. When the touch pen 76 is accommodated in the recessed part 74, the projection of the locking part 75 is elastically caught by the locked groove 76a. The projection of the locking part 75 that is caught by the locked groove 76a restrains the touch pen 76 from accidentally falling out of the second accommodation space S2.

The second accommodating part 57 is integrally formed with the walls 55A and 55C. The second accommodating part 57 is formed to have a substantially rectangular shape (quadrangle), and extends from the first edge portion 61 of the wall 55C along the wall 55A. In other words, the second accommodating part 57 is a portion projecting from the walls 55A and 55C. The second accommodating part 57 comprises a holding face 57a. The holding face 57a of the second accommodating part 57 is a face that is substantially in parallel with the first inner peripheral face 61a of the first edge portion 61 of the wall part 55A.

The second accommodating part 57 accommodates, for example, a magnet 78. When the display part 11 is in the closed position, a sensor arranged on the base unit 16 detects a magnetic force of the magnet 78 in the second accommodating part 57. With this configuration, the portable computer 10 detects that the display part 11 is in the closed position.

The wall 55A is spaced apart from the peripheral wall 46 that forms the lower end 21a of the first housing 21. A third accommodation space S3 is formed between the wall 55A and the peripheral wall 46 that forms the lower end 21a of the first housing 21.

The third accommodation space S3 is a gap between the wall 55A and the peripheral wall 46 that forms the lower end 21a of the first housing 21. The third accommodation space S3 extends along the wall 55A and the corresponding peripheral wall 46. Apart of the hinges 13 and an antenna are arranged in the third accommodation space S3.

As illustrated in FIG. 3, the display unit 22 comprises a display module 81, a digitizer module 82, and a touch panel 83. The display module 81 and the digitizer module 82 are examples of a first component and a display component, and may also be referred to as a displaying part, an input part, or an operation part, for example. The touch panel 83 is an example of a first member, and may also be referred to as a covering part, an input part, or an operation part, for example.

The display module 81 is, for example, a liquid crystal display (LCD). The display module 81 is not limited thereto, and may be a plasma display, an organic electroluminescence (EL) display, electronic paper, or another device that displays an image, for example. The display module 81 is formed to be a plate having a substantially rectangular shape (quadrangle).

As illustrated in FIG. 4, the display module 81 comprises a display face 81a, a back face 81b, and a side face 81c. The display module 81 displays an image on the display face 81a. Examples of the image described herein include a moving image, a static image, a monochrome screen, and characters. The back face 81b is positioned on a side opposite to the display face 81a. The side face 81c is substantially orthogonal to (intersects with) the display face 81a and the back face 81b.

Similarly to the display module 81, the digitizer module 82 is formed to be a plate having a substantially rectangular shape (quadrangle). The digitizer module 82 is fixed to the back face 81b of the display module 81. The digitizer module 82 may be integrally formed with the display module 81, for example. The digitizer module 82 comprises a side face 82a. The side face 82a of the digitizer module 82 is continuous with the side face 81c of the display module 81.

The touch panel 83 is, for example, an electrostatic capacitance type touch panel. The touch panel 83 may be a touch panel of another type such as a resistance film type. The touch panel 83 is formed to be a plate having a substantially rectangular shape (quadrangle).

The touch panel 83 comprises a surface 83a, a back face 83b, and a side face 83c. The surface 83a is made of, for example, a protective film, and is formed to be substantially flat. The back face 83b is positioned on a side opposite to the surface 83a, and is fixed to the display face 81a of the display module 81. The touch panel 83 may be detached from the display module 81. The side face 83c is substantially orthogonal to (intersects with) the surface 83a and the back face 83b.

The area of the surface 83a of the touch panel 83 is larger than the area of the display face 81a of the display module 81. That is, the touch panel 83 is larger than the display module 81.

As illustrated in FIG. 3, the touch panel 83 comprises a first portion 87 and a second portion 88. The first portion 87 may also be referred to as, for example, an inner part, a transmission part, a screen, an input part, an operation part, or a detection part. The second portion 88 may also be referred to as, for example, an outer part, a frame part, a surrounding part, a mask, a covering part, a supporting part, or a non-sensing part.

The first portion 87 is a transparent portion having a substantially rectangular shape (quadrangle). The first portion 87 may be colored. The area of the first portion 87 is approximately the same as the area of the display face 81a of the display module 81. The first portion 87 covers the display face 81a of the display module 81 and transmits an image displayed on the display face 81a.

A plurality of minute electrodes are provided to the first portion 87. The touch panel 83 detects, for example, a position where a finger of the user or the touch pen 76 are in contact with the face 83a of the touch panel 83 in the first portion 87. In other words, the first portion 87 detects a position input.

The second portion 88 is a portion having a frame shape that surrounds the first portion 87. The second portion 88 is positioned deviating from the display module 81. As illustrated in FIG. 4, the second portion 88 projects from the side face 81c of the display module 81.

The second portion 88 is, for example, painted in black. The second portion 88 may be painted in another color. As illustrated in FIG. 2, a logo 89 is provided to the second portion 88. The logo 89 may also be referred to as, for example, a displaying part, a design part, a figure, a mark, or characters. The logo 89 is, for example, a figure, and is formed by painting.

A wiring pattern is provided to the second portion 88. The wiring pattern is electrically connected to the corresponding electrode of the first portion 87. Unlike the first portion 87, the second portion 88 does not detect the position input.

The digitizer module 82 detects the position of the touch pen 76 in the first portion 87 of the touch panel 83 across the display module 81 and the touch panel 83. For example, the digitizer module 82 causes electromotive force to be generated in a coil that is provided to the touch pen 76 through electromagnetic induction. The touch pen 76 in which the electromotive force is generated in the coil outputs a signal to the digitizer module 82. The digitizer module 82 detects the position of the touch pen 76 by receiving the signal.

As illustrated in FIG. 4, the digitizer module 82 is supported by the second supporting face 63a of the supporting part 63 of the frame 42 and the third supporting face 71a of the battery 71. In other words, the battery 71 is arranged between the back cover 41 and the digitizer module 82, and the third supporting face 71a of the battery 71 faces the digitizer module 82.

In FIG. 2, the display module 81 and the digitizer module 82 are represented by a two-dot chain line. As illustrated in FIG. 2, the display module 81 and the digitizer module 82 are surrounded by the four walls 55.

The first inner peripheral face 61a of the first edge portion 61 of the walls 55B and 55C and the holding face 57a of the second accommodating part 57 are in contact with the side face 81c of the display module 81 and the side face 82a of the digitizer module 82. The first face 56a of the first accommodating part 56 is in contact with at least one of the side face 81c of the display module 81 and the side face 82a of the digitizer module 82. In other words, the first face 56a of the first accommodating part 56 faces the display module 81 and the digitizer module 82. A gap may be formed between the first inner peripheral face 61a of the first edge portion 61 as well as the holding face 57a of the second accommodating part 57 and the side face 81c of the display module 81 as well as the side face 82a of the digitizer module 82. A gap may be formed between the first face 56a of the first accommodating part 56 and the side face 81c of the display module 81 as well as the side face 82a of the digitizer module 82.

The walls 55B and 55C, the first accommodating part 56, and the second accommodating part 57 hold the display module 81 and the digitizer module 82. That is, movement of the display module 81 and the digitizer module 82 in a direction along the X-axis and the Y-axis is limited by the walls 55B and 55C, the first accommodating part 56, and the second accommodating part 57.

The display module 81 and the digitizer module 82 are spaced apart from the wall 55D, the display module 81 and the digitizer module 82 being held by the walls 55B and 55C, the first accommodating part 56, and the second accommodating part 57. A fourth accommodation space S4 is formed between the display module 81 as well as the digitizer module 82 and the wall 55D. The fourth accommodation space S4 is an example of a gap formed between the first component and the first wall, and may also be referred to as an accommodating part, a storage part, or a space, for example.

The fourth accommodation space S4 is a gap extending from the end portion of the first accommodating part 56 to the wall part 55C along the wall 55D. A first camera module 91, a first control substrate 92, and a second camera module 93 are arranged in the fourth accommodation space S4. The first camera module 91, the first control substrate 92, and the second camera module 93 are examples of a third component.

The first camera module 91 is arranged adjacent to the first accommodating part 56. The first camera module 91 photographs an image in front of the display part 11. The first control substrate 92 is electrically connected to the touch panel 83. The first control substrate 92 is, for example, a PCB, and controls the touch panel 83.

The second camera module 93 is arranged adjacent to the wall 55C. The second camera module 93 photographs an image in the rear of the display part 11. The second camera module 93 comprises a sensor 93a and a controller 93b.

The sensor 93a comprises an image sensor. The sensor 93a photographs the rear of the display part 11 through a hole provided on the back wall 45. The controller 93b is, for example, a PCB that is spaced apart from the sensor 93a and extends along the wall 55C. The controller 93b is electrically connected to, for example, the sensor 93a via a cable, and controls the sensor 93a.

The second camera module 93 is attached to the back cover 41 and the frame 42 with tape 96. The tape 96 comprises, for example, a portion formed of metal. Heat generated in the sensor 93a is conducted to the back cover 41 and the frame 42 via the tape 96. The sensor 93a is cooled by the tape 96.

The first accommodating part 56 is formed between the wall 55D and the display module 81 as well as the digitizer module 82. The fourth accommodation space S4 is formed between the wall 55D and the display module 81 as well as the digitizer module 82, the first camera module 91, the first control substrate 92, and the second camera module 93 arranged in the fourth accommodation space S4. In other words, the first accommodating part 56, the first camera module 91, the first control substrate 92, and the second camera module 93 are aligned in the gap between the wall 55D and the display module 81 as well as the digitizer module 82.

The display module 81 and the digitizer module 82 are spaced apart from the wall part 55A, the display module 81 and the digitizer module 82 being held by the walls 55B and 55C, the first accommodating part 56, and the second accommodating part 57. A fifth accommodation space S5 is formed between the display module 81 as well as the digitizer module 82 and the wall 55A.

The fifth accommodation space S5 is a gap extending from the end of the second accommodating part 57 to the wall 55B along the wall 55A. A second control substrate 97 is arranged in the fifth accommodation space S5.

The second control substrate 97 is arranged adjacent to the second accommodating part 57. The second control substrate 97 is fixed to the side face 81c of the display module 81, and is electrically connected to the display module 81. The second control substrate 97 is, for example, a PCB, and controls the display module 81.

The second accommodating part 57 is between the wall 55A and the display module 81 as well as the digitizer module 82. The fifth accommodation space S5 in which the second control substrate 97 is arranged is formed between the wall 55A and the display module 81 as well as the digitizer module 82. In other words, the second accommodating part 57 and the second control substrate 97 are aligned between the wall 55A and the display module 81 as well as the digitizer module 82.

As illustrated in FIG. 4, double-sided tape 98 is attached to the first supporting face 61b of the first edge 61 of the wall 55. The double-sided tape 98 fixes the second portion 88 of the touch panel 83 to the first supporting face 61b of the first edge 61. The touch panel 83 may be fixed to the first edge 61 with another member such as an adhesive agent.

The second portion 88 of the touch panel 83 is supported by the first supporting face 61b of the first edge 61 via the double-sided tape 98. The second face 56b of the first accommodating part 56 supports the second portion 88 of the touch panel 83 together with the first edge 61. In other words, the first accommodating part 56 is covered with the second portion 88 of the touch panel 83.

The second edge 62 of the wall 55 surrounds the touch panel 83. The side face 83c of the touch panel 83 is in contact with the second inner peripheral face 62a of the second edge 62. The second edge 62 of the wall 55 limits the movement of the touch panel 83 in the direction along the X-axis and the Y-axis, and holds the touch panel 83. A gap may be formed between the side face 83c of the touch panel 83 and the second inner peripheral face 62a of the second edge 62.

In the direction along the Z-axis, the frame 42, the battery 71, the display module 81, and the digitizer module 82 are arranged between the back cover 41 and the touch panel 83. In other words, the back cover 41 and the touch panel 83 cover the frame 42, the battery 71, the display module 81, and the digitizer module 82.

As illustrated in FIG. 2, the display part 11 further comprises cables 101A, 101B, and 101C. The cable 101A is electrically connected to, for example, the digitizer module 82, the first control substrate 92, and the second control substrate 97. The cable 101B is electrically connected to, for example, the battery 71. The cable 101C is electrically connected to, for example, the switch 68, the first camera module 91, and the second camera module 93.

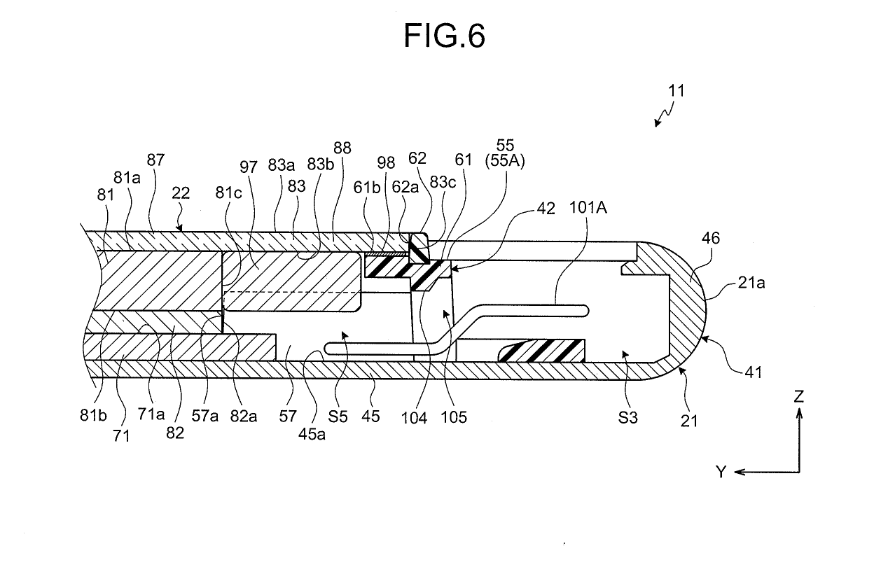

FIG. 6 is a cross-sectional view illustrating a part of the display part 11 along the line F6-F6 in FIG. 2. As illustrated in FIG. 6, three cut-outs 104 are arranged on the wall 55A. The cut-outs 104 are examples of an inserting part and a third recessed part. The three cut-outs 104 are arranged in the longitudinal direction of the wall 55A. An end portion of each of the cut-outs 104 is opened toward the back wall 45.

When the frame 42 is mounted to the back cover 41, the opened end portion of the cut-out 104 is covered with the back wall 45. The cut-out 104 the end portion of which is covered with the back wall 45 forms a second inserting hole 105. The second inserting hole 105 is an example of a second opening.

Each of the cables 101A, 101B, and 101C passes through the corresponding second inserting hole 105, and is introduced into the third accommodation space S3. Each of the cables 101A, 101B, and 101C passes through the hinge part 13 that is partially arranged in the third accommodation space S3, and is electrically connected to the substrate of the base unit 16.

As illustrated in FIG. 1, the first housing 21 further comprises a bezel 107. The bezel 107 is made of, for example, synthetic resin. The bezel 107 is supported by the back cover 41 and the frame 42, and positioned on aside opposite to the back wall 45. The bezel 107 covers the third accommodation space S3. The antenna accommodated in the third accommodation space S3 performs communication through the bezel 107.

In the portable computer 10 according to the first embodiment, the display module 81, the digitizer module 82, and the first accommodating part 56 that can accommodate the touch pen 76 are arranged inside the wall 55. With this configuration, the display module 81, the digitizer module 82, and the first accommodating part 56 can be densely arranged inside the frame 42, and the size and the thickness of the portable computer 10 are reduced.

In a gap between the wall 55D and the display module 81 as well as the digitizer module 82, the first camera module 91, the first control substrate 92, and the second camera module 93 are arranged in addition to the first accommodating part 56. With this configuration, a plurality of components can be densely arranged inside the frame 42, and the size of the portable computer 10 is reduced.

The walls 55B and 55C, the first accommodating part 56, and the second accommodating part 57 limit the movement of the display module 81 and the digitizer module 82, and hold the display module 81 and the digitizer module 82. With this configuration, the display module 81, the digitizer module 82, and the first accommodating part 56 are arranged in the frame 42 without using another portion or member for holding them. Due to this, a plurality of components can be densely arranged inside the frame 42, and the size of the portable computer 10 is reduced.

The wall 55 and the first accommodating part 56 are integrally formed with each other. This reduces the number of components, so that component cost and mold cost for the portable computer 10 are reduced. This can reduce the production cost of the portable computer 10. In addition, the first accommodating part 56 can be formed to be small, and the fourth accommodation space S4 can be enlarged.

The wall part 55 supports the touch panel 83. Due to this, the touch panel 83 can be supported without using another component or portion for supporting the touch panel 83. This can reduce the production cost of the portable computer 10.

The first accommodating part 56 supports the touch panel 83 together with the wall 55. With this configuration, an area for supporting the touch panel 83 is increased and the touch panel 83 is stably supported, and the touch panel 83 is restrained from being damaged due to stress concentration.

The wall part 55 and the first accommodating part 56 support the second portion 88 of the touch panel 83. With this configuration, the wall 55 and the first accommodating part 56 are restrained from damaging an image transmission function of the touch panel 83.

The first accommodating part 56 is arranged side by side with the display module 81 for displaying an image, and surrounded by the wall 55. With this configuration, the thickness of the first housing 21 in which the display module 81 is accommodated is restrained from being increased, and the thickness of the portable computer 10 is reduced.

The first accommodating part 56 comprises the recessed part 74, and the touch pen 76 is accommodated in the second accommodation space S2 formed by the recessed part 74. Due to this, the first accommodating part 56 is simplified. For example, in molding using a die, it is easier to form the recessed part than to form a hole. With this configuration, the portable computer 10 is easily manufactured.

The wall 55A comprises the cut-out 104 through which the cables 101A, 101B, and 101C pass. In other words, the wall 55A holds the cables 101A, 101B, and 101C. With this configuration, the cables 101A, 101B, and 101C are easily arranged.

The end portion of the cut-out 104 of the wall 55A is covered with the back wall 45 to form the second inserting hole 105. The cables 101A, 101B, and 101C pass through the second inserting hole 105. With this configuration, the second inserting hole 105 through which the cables 101A, 1013, and 101C pass is easily formed.

The wall 55B comprises the groove 67 that is covered with the back cover 41 and accommodates the button 52. That is, the button 52 is held by the wall 55, so that another component or member for holding the button 52 is not required and the production cost of the portable computer 10 is reduced.

The battery 71 is arranged between the back cover 41 and the digitizer module 82. Due to this, another portion or member for holding the battery 71 is not required, a plurality of components can be densely arranged inside the frame 42, and the size of the portable computer 10 is reduced. The battery 71 comprises the third supporting face 71a facing the digitizer module 82, so that the digitizer module 82 is restrained from being damaged by projections and depressions.

The second edge portion 62 being in contact with the touch panel 83 has higher elasticity than that of the first edge portion 61. This configuration requires no extra member for restraining the touch panel 83 from being damaged, whereby the number of components of the portable computer 10 is reduced and the production cost of the portable computer 10 is reduced.

The display module 81 is fixed to the touch panel 83, and the touch panel 83 is fixed to the wall 55 with the double-sided tape 98. This configuration requires no extra component such as a screw for directly fixing the display module 81 to the wall 55, whereby the number of components of the portable computer 10 is reduced and the production cost of the portable computer 10 is reduced.

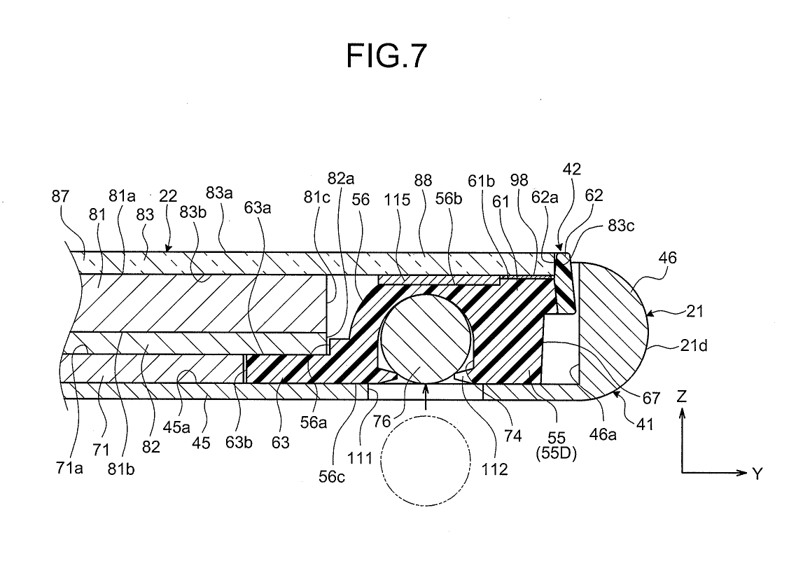

The following describes a second embodiment with reference to FIG. 7. In the following description of the embodiment, a component having the same function as that of the component described above is denoted by the same reference numeral as the above-described component, and the description thereof may be omitted in some cases. A plurality of components denoted by the same reference numeral do not necessarily have completely the same function and characteristic. The function and the characteristic thereof may be different corresponding to the embodiments.

FIG. 7 is a cross-sectional view illustrating part of the display part 11 according to the second embodiment. As illustrated in FIG. 7, the back cover 41 comprises an insertion opening 111 instead of the insertion opening 51 of the peripheral wall 46. The insertion opening 111 is an example of a first opening.

The insertion opening 111 is an opening provided on the back wall 45 and extending along the recessed part 74. The insertion opening 111 causes the recessed part 74 opened toward the third face 56c of the first accommodating part 56 to be opened. The insertion opening 111 is larger than the recessed part 74 opened toward the third face 56c. The touch pen 76 is inserted from the insertion opening 111 into the recessed part 74.

The recessed part 74 comprises a holding part 112. The holding part 112 is, for example, a claw that can be elastically deformed. The touch pen 76 inserted into the recessed part 74 is elastically caught by the holding part 112, and held in the recessed part 74.

The display part 11 further comprises an antenna 115. The antenna 115 comprises, for example, a sheet and a circuit formed on the sheet. The antenna 115 is mounted on the second face 56b of the first accommodating part 56.

The second portion 88 of the touch panel 83 is supported by the second face 56b of the first accommodating part 56 via the antenna 115. In other words, the antenna 115 is arranged between the first accommodating part 56 and the second portion 88 of the touch panel 83.

The wiring pattern arranged on the second portion 88 is formed while avoiding the antenna 115. That is, the antenna 115 is not covered with a conductive portion of the touch panel 83. The antenna 115 inputs/outputs an electromagnetic wave through the touch panel 83.

In the portable computer 10 according to the second embodiment, the antenna 115 is arranged between the touch panel 83 and the first accommodating part 56. With this configuration, even if the back cover 41 is a conductive component, the antenna 115 can perform communication through the touch panel 83. In addition, a plurality of components including the antenna 115 can be densely arranged inside the frame 42, and the size of the portable computer 10 is reduced.

According to at least one of the embodiments described above, a plurality of first walls of a wall member surround a first component, and a gap and an accommodating part are provided between at least one of the first walls and the first component. With this configuration, the thickness of the electronic device can be reduced.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

For example, in the above embodiments, the display module 81 and the digitizer module 82 are examples of the first component, and the first accommodating part 56 that is an example of the accommodating part is provided to the display part 11. However, the first component may be, for example, another component such as a battery or a substrate, and the accommodating part may be provided to another place such as the base 12.

In the above embodiments, the wall part 55 that is an example of the first wall is covered with the peripheral wall 46 of the back cover 41. However, the first wall may be exposed to the outside.

In the above embodiments, the touch panel 83 is an example of the first member. However, the first member may be another component such as an organic EL display. When the first member is the organic EL display, a first portion of the first member displays an image.

What is claimed is:

1. An electronic device comprising:
a first component;
a wall member comprising a plurality of first walls surrounding the first component, a gap formed between at least one of the first walls and the first component; and
an accommodating part between the first component and the at least one of the first walls, and configured to accommodate a second component.

2. The electronic device of claim 1, further comprising a third component in the gap.

3. The electronic device of claim 2, wherein
the accommodating part comprises a second wall facing the first component, and
the at least one of the first walls and the second wall are configured to limit movement of the first component.

4. The electronic device of claim 3, wherein the wall member and the accommodating part are integrally formed.

5. The electronic device of claim 4, further comprising a first member configured to cover the first component, wherein the first walls are configured to support the first member.

6. The electronic device of claim 5, wherein the accommodating part is configured to support the first member together with the first walls.

7. The electronic device of claim 6, wherein
the first member comprises a first portion configured to display or transmit an image and a second portion configured to surround the first portion, and
the first walls and the accommodating part are configured to support the second portion of the first member.

8. The electronic device of claim 7, wherein
the first component is configured to display an image, and
the first portion of the first member is configured to transmit the image displayed by the first component.

9. The electronic device of claim 8, wherein the first walls comprise:
a first formed portion comprising a first material; and
a second formed portion integrally formed with the first formed portion, configured to be in contact with the first member, and comprising a second material having higher elasticity than that of the first material.

10. The electronic device of claim 9, wherein
the first component is configured to be fixed to the first member, and
the first member is configured to be fixed to the first walls.

11. The electronic device of claim 10, further comprising an antenna between the first member and the accommodating part.

12. The electronic device of claim 10, wherein the first portion of the first member is configured to detect a position input, and the second portion of the first member is configured not to detect the position input.

13. The electronic device of claim 1, further comprising a housing comprising the wall member and a first opening opened toward outside, wherein
the accommodating part is configured to be connected to the first opening, and the second component is insertable from the first opening.

14. The electronic device of claim 13, further comprising a second member configured to cover the first component, wherein
the accommodating part comprises a first recessed part connected to the first opening and covered with the second member, and is configured to accommodate the second component in the first recessed part covered with the second member.

15. The electronic device of claim 14, further comprising a fourth component, wherein
the second member comprises a plurality of third walls that are in contact with the first walls, respectively, and
at least one of the first walls is covered with at least one of the third walls and comprises a second recessed part configured to accommodate the fourth component.

16. The electronic device of claim 15, further comprising a fifth component between the second member and the first component, surrounded by the first walls, and comprising a flat face facing the first component.

17. The electronic device of claim 16, wherein
the first component comprises a cable, and
at least one of the first walls comprises an inserting part configured to pass through the cable.

18. The electronic device of claim 17, wherein
the inserting part comprises a third recessed part configured to form a second opening covered with the second member at an end portion thereof, and
the cable is configured to pass through the second opening.

19. The electronic device of claim 1, wherein the second component comprises a pen.

20. An electronic device comprising:
a display component configured to display an image; and
a frame member configured to surround the display component, the frame member comprising an accommodating part configured to accommodate a pen.
